(19) United States
(12) Patent Application Publication
(10) Pub. No.: US 2026/0123092 A1
(43) Pub. Date: Apr. 30, 2026

(54) SOLAR CELL AND PREPARATION METHOD OF SOLAR CELL

(71) Applicant: SHINE OPTOELECTRONICS (KUNSHAN) CO., LTD., Kunshan (CN)

(72) Inventor: Yulong GAO, Kunshan (CN)

(73) Assignee: SHINE OPTOELECTRONICS (KUNSHAN) CO., LTD., Kunshan (CN)

(21) Appl. No.: 19/003,309

(22) Filed: Dec. 27, 2024

Related U.S. Application Data
(63) Continuation of application No. PCT/CN2023/124266, filed on Oct. 12, 2023.

(30) Foreign Application Priority Data
Oct. 12, 2022 (CN) 202211249715.1

(51) Int. Cl. H10F 77/20; H10F 10/164; H10F 71/00; H10F 71/10

(52) U.S. Cl. CPC H10F 77/215; H10F 10/164; H10F 71/103; H10F 71/138; H10F 77/247

(57) ABSTRACT

A solar cell includes a substrate, a transparent conductive film layer and a composite metal grid structure. The transparent conductive film layer is disposed on a side or both sides of the substrate; and the composite metal grid structure is disposed on a side, away from the substrate, of the transparent conductive film layer, and the transparent conductive film layer is electrically connected to the composite metal grid structure. The composite metal grid structure includes a first electrode layer and a second electrode layer, and the first electrode layer is located between the transparent conductive film layer and the second electrode layer. The composite metal grid structure including the first electrode layer and the second electrode layer is used in the solar cell, so that stability is relatively high, consumption of silver may be reduced to lower costs, electrical performance is good, and conversion efficiency can be improved.

### CROSS-REFERENCE TO RELATED APPLICATIONS

This application is a continuation of International Application No. PCT/CN2023/124266, filed on Oct. 12, 2023, which claims priority to Chinese Patent Application No. 202211249715.1 filed on Oct. 12, 2022. The disclosures of the aforementioned applications are hereby incorporated by reference in their entireties.

### TECHNICAL FIELD

The present disclosure relates to the field of solar cell technologies, and in particular, to a solar cell and a preparation method of the solar cell.

### BACKGROUND

In the field of solar cells, heterojunction solar cells are one of highly promising high-efficiency solar cells. The heterojunction solar cells have advantages of simple preparation process flow, high conversion efficiency, capable of being large size, capable of being thin, low attenuation, good double-sided performance and the like, and has been researched and produced by numerous manufacturers.

In a common heterojunction solar cell, silver grid lines are formed by screen printing silver paste on a transparent conductive film layer, which leads to relatively low stability and high consumption of the silver paste, thereby resulting in relatively high costs.

### SUMMARY

In view of this, the present disclosure provides a solar cell and a preparation method of the solar cell, which aims to solve at least one of the above technical problems.

A first aspect of the present disclosure provides a solar cell provided with a composite metal grid structure, which includes: a substrate; a transparent conductive film layer disposed on a or both sides of the substrate; and a composite metal grid structure disposed on a side, away from the substrate, of the transparent conductive film layer, the transparent conductive film layer being electrically connected to the composite metal grid structure; and the composite metal grid structure includes a first electrode layer and a second electrode layer that are stacked, and the first electrode layer is located between the transparent conductive film layer and the second electrode layer.

In an embodiment of the present disclosure, the composite metal grid structure further includes an anti-oxidation protection layer wrapping the first electrode layer and the second electrode layer.

In an embodiment of the present disclosure, the first electrode layer is a silver seed layer, and the second electrode layer is a copper electrode layer.

In an embodiment of the present disclosure, a width of the composite metal grid structure is less than or equal to 17 μm.

In an embodiment of the present disclosure, an aspect ratio of the composite metal grid structure is greater than 0.5.

In an embodiment of the present disclosure, the solar cell is a crystalline silicon solar cell or an amorphous silicon solar cell.

In an embodiment of the present disclosure, the substrate includes a first side surface and a second side surface opposite to each other, and the transparent conductive film layer is an Indium Tin Oxide (ITO) layer that is arranged, as an entire surface, on at least one of the first side surface or the second side surface.

In an embodiment of the present disclosure, the substrate includes a first side surface and a second side surface opposite to each other, at least one of the first side surface or the second side surface is a textured surface, a height difference on the textured surface is not greater than 2 μm, and the transparent conductive film layer is conformally arranged with the textured surface.

In an embodiment of the present disclosure, the composite metal grid structure is arranged in a linear shape and/or a grid shape, and a transmittance of the composite metal grid structure is greater than 80%.

In an embodiment of the present disclosure, the composite metal grid structure is in a polygonal grid shape, a circular grid shape, or a random grid shape.

In an embodiment of the present disclosure, the first electrode layer is a coating layer having a thickness not greater than 800 nm, or the first electrode layer is a sintered layer having a thickness not greater than 3 μm; and the second electrode layer is a sintered layer or a coating layer, and the second electrode layer has a thickness ranging from 5 μm to 60 μm and a width ranging from 3 μm to 80 μm.

In an embodiment of the present disclosure, the solar cell further includes a transparent insulating layer, the transparent insulating layer is disposed on a side, away from the substrate, of the transparent conductive film layer, the transparent insulating layer is provided with a trench, and the composite metal grid structure is disposed in the trench and is in electrical contact with the transparent conductive film layer.

In an embodiment of the present disclosure, the substrate includes a first side surface and a second side surface opposite to each other, the first side surface of the substrate is provided with the transparent conductive film layer and the composite metal grid structure, and the second side surface is provided with an anti-reflection layer.

A second aspect of the present disclosure provides a preparation method of a solar cell, which includes: S1, providing a substrate; S2, preparing a transparent conductive film layer on the substrate; S3, preparing a first electrode layer in a grid shape on the transparent conductive film layer; and S4, forming a second electrode layer on the first electrode layer to obtain a composite metal grid structure including the first electrode layer and the second electrode layer.

In an embodiment of the present disclosure, the step S3 includes: disposing curing resin on the transparent conductive film layer, imprinting and curing the curing resin to form a trench in a grid shape, and removing the curing resin at a bottom of the trench to form a transparent insulating layer, the transparent conductive film layer being exposed in the trench; and filling the trench with silver paste and sintering the silver paste to form a silver seed layer serving as the first electrode layer, or performing electroplating or electroless plating in the trench to form a silver seed layer serving as the first electrode layer.

In an embodiment of the present disclosure, the step S3 includes: disposing a photoresist on the transparent conductive film layer, exposing and developing the photoresist to form a transparent insulating layer with a trench in a grid shape, the transparent conductive film layer being exposed in the trench; and filling the trench with silver paste and sintering the silver paste to form a silver seed layer serving as the first electrode layer, or performing electroplating or electroless plating in the trench to form a silver seed layer serving as the first electrode layer.

In an embodiment of the present disclosure, the preparation method further includes: removing the transparent insulating layer.

In an embodiment of the present disclosure, the preparation method includes: preparing an anti-oxidation protection layer, and the anti-oxidation protection layer at least wraps the first electrode layer and the second electrode layer.

In an embodiment of the present disclosure, the step S4 includes: forming a copper electrode layer serving as the second electrode layer on the first electrode layer by electroplating, electroless plating, or filling followed by sintering.

The beneficial effects of the present disclosure are as follows: the composite metal grid structure including the first electrode layer and the second electrode layer that are stacked is used in the solar cell, so that a structural stability is relatively high, consumption of silver is reduced to lower costs, electrical performance is good, and conversion efficiency can be improved.

### BRIEF DESCRIPTION OF THE DRAWINGS

FIG. 1 is a schematic structural diagram of a solar cell provided with a composite metal grid structure according to the present disclosure.

FIG. 2 is a schematic structural diagram of a substrate of a solar cell provided with a composite metal grid structure according to the present disclosure.

FIG. 3 is a schematic structural diagram of a solar cell provided with a composite metal grid structure according to another embodiment of the present disclosure.

FIG. 4 is a schematic structural diagram of a solar cell provided with a composite metal grid structure according to another embodiment of the present disclosure.

FIG. 5 is a schematic structural diagram of a solar cell provided with a composite metal grid structure according to another embodiment of the present disclosure.

FIG. 6 is a schematic structural diagram of a solar cell provided with a composite metal grid structure according to another embodiment of the present disclosure.

FIG. 7 is a schematic structural diagram of a solar cell provided with a composite metal grid structure according to another embodiment of the present disclosure.

FIG. 8 is a schematic structural diagram of a solar cell provided with a composite metal grid structure according to another embodiment of the present disclosure.

FIG. 9 is a schematic structural diagram of a solar cell provided with a composite metal grid structure according to another embodiment of the present disclosure.

FIG. 10 is a schematic structural diagram of a solar cell provided with a composite metal grid structure according to another embodiment of the present disclosure.

FIG. 11 is a schematic flowchart of a preparation method of a solar cell provided with a composite metal grid structure according to the present disclosure.

### DETAILED DESCRIPTION OF THE EMBODIMENTS

In order to facilitate understanding of the present disclosure, the present disclosure will be described more fully hereinafter with reference to the accompanying drawings. Preferred embodiments of the present disclosure are shown in the accompanying drawings. However, the present disclosure may be implemented in many different forms and is not limited to the embodiments described below. On the contrary, the purposes of providing these embodiments are to make the disclosures of the present disclosure more thorough and comprehensive.

Unless otherwise defined, all technical and scientific terms used herein have the same meaning as commonly understood by one of ordinary skill in the art to which the present disclosure belongs. The terms used in the specification of the present disclosure are merely for the purposes of describing specific embodiments, and are not intended to limit the present disclosure. As used herein, the term “and/or” includes any and all combinations of the listed items, individually or collectively.

A common heterojunction solar cell is prepared by taking an N-type monocrystalline silicon wafer as a substrate, depositing intrinsic amorphous silicon and N-type doped amorphous silicon on a front side after texturing and cleaning, sequentially depositing intrinsic amorphous silicon and P-type doped amorphous silicon on a back side to form a PN junction, respectively depositing a transparent conductive film layer on the front side and the back side, and respectively printing silver grid lines on the front side and the back side. However, the silver grid lines are formed by screen printing silver paste on the transparent conductive film layer, which leads to relatively low stability and high consumption of the silver paste, thereby resulting in relatively high costs.

The present disclosure discloses a solar cell provided with a composite metal grid structure, which includes a substrate, a transparent conductive film layer, and a composite metal grid structure. The transparent conductive film layer is disposed on a side or both sides of the substrate; and the composite metal grid structure is disposed on a side, away from the substrate, of the transparent conductive film layer, and the transparent conductive film layer is electrically connected to the composite metal grid structure. The composite metal grid structure includes a first electrode layer and a second electrode layer that are stacked, and the first electrode layer is located between the transparent conductive film layer and the second electrode layer. The composite metal grid structure including the first electrode layer and the second electrode layer that are stacked is used, so that structural stability is relatively high, consumption of silver is reduced to lower costs, electrical performance is good, and conversion efficiency can be improved.

In some embodiments, the solar cell of the present disclosure has a single-sided structure, and only one side of the substrate is provided with the transparent conductive film layer and the composite metal grid structure. In another embodiment, the solar cell of the present disclosure has a double-sided structure, and both sides of the substrate are provided with the transparent conductive film layer and the composite metal grid structure.

In some embodiments, the substrate includes a silicon wafer, intrinsic amorphous silicon and N-type doped amorphous silicon located on a side of the silicon wafer, and intrinsic amorphous silicon and P-type doped amorphous silicon located on another side of the silicon wafer. The silicon wafer may be made of N-type doped monocrystalline silicon, N-type doped quasi-single crystal silicon, P-type doped monocrystalline silicon, or P-type doped quasi-single crystal silicon. The intrinsic amorphous silicon is one or more of undoped amorphous silicon, amorphous silicon oxide, and amorphous silicon carbide. The N-type doped amorphous silicon is one or more of N-type doped amorphous silicon, amorphous silicon oxide, amorphous silicon carbide, microcrystalline silicon, microcrystalline silicon oxide, and microcrystalline silicon carbide. The P-type doped amorphous silicon is one or more of P-type doped amorphous silicon, amorphous silicon oxide, amorphous silicon carbide, microcrystalline silicon, microcrystalline silicon oxide, and microcrystalline silicon carbide. The substrate may be a crystalline silicon substrate or an amorphous silicon substrate, and correspondingly, the resulting solar cell is a crystalline silicon solar cell or an amorphous silicon solar cell. The solar cell is a crystalline silicon solar cell or an amorphous silicon solar cell, preferably a heterojunction solar cell.

In some embodiments, the composite metal grid structure further includes an anti-oxidation protection layer wrapping the first electrode layer and the second electrode layer. The anti-oxidation protection layer may further cover, with an entire surface, a side, provided with the second electrode layer, of the transparent conductive film layer, so that both the second electrode layer and a portion of the transparent conductive film layer exposed between adjacent second electrode layers (i.e., a portion, not covered by the second electrode layer, of the transparent conductive film layer) are covered by the anti-oxidation protection layer.

In some embodiments, the first electrode layer is a silver seed layer, which has relatively good electrical performance. In other embodiments, the first electrode layer may also be a copper seed layer or a seed layer of another metal. The second electrode layer is a copper electrode layer or an electrode layer of another metal. The composite metal grid structure is formed by connecting a seed layer to an electrode layer, which results in good structural stability and good electrical performance, and is beneficial to reducing consumption of silver paste, thereby lowering costs.

In some embodiments, a width of the composite metal grid structure is less than or equal to 17 μm, and thus the composite metal grid structure has relatively good electrical performance. A height of the composite metal grid structure is greater than or equal to or less than the width. In an embodiment, an aspect ratio of the composite metal grid structure is greater than 0.5, so that the composite metal grid structure has both a relatively high transmittance and relatively good electrical performance.

In some embodiments, the substrate includes a first side surface and a second side surface opposite to each other, and the transparent conductive film layer is an ITO layer that is disposed, as an entire surface, on at least one of the first side surface or the second side surface. A material of the ITO layer is formed by mixing 90% In₂O₃ and 10% SnO₂. The ITO layer may be disposed only on one of the first side surface of the substrate or the second side surface of the substrate, or on both the first side surface and the second side surface. In other embodiments, the ITO layer may also be replaced by an aluminum-doped zinc oxide (AZO) layer, i.e., the transparent conductive film layer may also be the AZO layer that is disposed, as an entire surface, on at least one of the first side surface or the second side surface.

In some embodiments, at least one of the first side surface of the substrate or the second side surface of the substrate is a textured surface, a silicon wafer is cleaned and textured to form an uneven textured surface, and a height difference on the textured surface is not greater than 2 μm. The transparent conductive film layer is conformally arranged with the textured surface, i.e., the transparent conductive film layer also has an uneven surface. Therefore, in a case that the first electrode layer is in direct contact with the transparent conductive film layer, a side, in contact with the transparent conductive film layer, of the first electrode layer is uneven, and another side of the first electrode layer may be uneven or flat; a shape of the second electrode layer at a side, in contact with the first electrode layer, of the second electrode layer conforms to a shape of the first electrode layer (i.e., in a case that a side, away from the transparent conductive film layer, of the first electrode layer has an uneven surface, a side, in contact with the first electrode layer, of the second electrode layer also has an uneven surface; and in a case that the side, away from the transparent conductive film layer, of the first electrode layer has a flat surface, the side, in contact with the first electrode layer, of the second electrode layer also has a flat surface), and another side of the second electrode layer is flat.

In some embodiments, the composite metal grid structure is arranged in a linear shape and/or a grid shape, and thus a transmittance of the composite metal grid structure is greater than 80%. In a case that the composite metal grid structure is in the linear shape, the linear shape may include a plurality of lines set in parallel, for example, the plurality of lines may be arranged horizontally, vertically or obliquely; and in a case that the composite metal grid structure is in the grid shape, the grid shape may be a polygonal grid shape, a circular grid shape, or a random grid shape, for example, the grid may be one or a combination of a plurality of shapes such as a square, a rectangle, a parallelogram, a honeycomb, a circle, an ellipse, a special shape, or an irregular shape. Therefore, the composite metal grid structure may have a relatively high transmittance, thereby improving electrical performance and conversion efficiency.

In some embodiments, the first electrode layer is a coating layer, and a thickness of the first electrode layer is not greater than 800 nm; or, the first electrode layer is a sintered layer, and the thickness of the first electrode layer is not greater than 3 μm. In this way, consumption of silver paste can be greatly reduced to lower costs, and electrical performance requirements can be met.

In some embodiments, the second electrode layer is a sintered layer or a coating layer, the second electrode layer has a thickness ranging from 10 μm to 60 μm and a width ranging from 3 μm to 80 μm, and thus the second electrode layer has relatively good electrical performance.

Exemplarily, in an embodiment, the first electrode layer is a silver seed layer, and the second electrode layer is a copper electrode layer. The silver seed layer may be formed by filling silver paste and sintering the silver paste, or may be formed by electroplating or electroless plating. The copper electrode layer (i.e., the second electrode layer) may be formed on the silver seed layer (i.e., the first electrode layer) by electroplating, electroless plating, or filling followed by sintering, which may greatly reduce consumption of silver, thereby lowering costs. In addition, the copper electrode layer also has a relatively good electrical conductivity.

In some embodiments, the composite metal grid structure further includes a tin layer located on the second electrode layer, a thickness of the tin layer ranges from 5 nm to 50 nm, and the tin layer may play a role in protecting the second electrode layer, so that electrical performance is improved.

In some embodiments, the solar cell further includes a transparent insulating layer disposed on a side, away from the substrate, of the transparent conductive film layer, the transparent insulating layer is provided with a trench, and the composite metal grid structure is disposed in the trench and is in electrical contact with the transparent conductive film layer. The transparent insulating layer may be a transparent adhesive layer that is not washed off during a production process, or may be an additional transparent adhesive layer. The transparent insulating layer may play a role in protecting the composite metal grid structure without affecting an illumination effect, thereby ensuring conversion efficiency.

In some embodiments, the first side surface of the substrate is provided with the transparent conductive film layer and the composite metal grid structure, and the second side surface is provided with an anti-reflection layer. The transparent conductive film layer and the composite metal grid structure are disposed on a power generation surface of the solar cell, and the anti-reflection layer is disposed on a back side. In a case that the solar cell does not need to be turned over in an application scenario (i.e., there is no need to provide a double-sided power generation structure), disposing the anti-reflection layer on the back side of the solar cell may enhance illumination and improve conversion efficiency.

The present disclosure further discloses a preparation method of a solar cell provided with a composite metal grid structure, which includes the following steps:
S1, providing a substrate;
S2, preparing a transparent conductive film layer on the substrate;
S3, preparing a first electrode layer in a grid shape on the transparent conductive film layer; and
S4, forming a second electrode layer on the first electrode layer to obtain a composite metal grid structure.

A process of the preparation method of the solar cell is simple, and the resulting solar cell exhibits a stable structure, good electrical performance and relatively high conversion efficiency.

In some embodiments, the step S3 may specifically include:
disposing curing resin on the transparent conductive film layer, imprinting and curing the curing resin to form a trench in a grid shape, and removing the curing resin at a bottom of the trench to form a transparent insulating layer, the transparent conductive film layer being exposed in the trench of the transparent insulating layer; and
filling the trench with silver paste and sintering the silver paste to form a silver seed layer serving as the first electrode layer, or, performing electroplating or electroless plating in the trench to form a silver seed layer serving as the first electrode layer.

Preferably, the curing resin is Ultraviolet (UV) resin, and the residual resin at the bottom of the trench after imprinting and curing is removed by cleaning or etching. After the transparent conductive film layer is exposed in the trench, the silver seed layer (i.e., the first electrode layer) may be formed on the transparent conductive film layer that is exposed in the trench by electroplating or electroless plating, or the silver seed layer may be formed by filling the silver paste in the trench through a manner of doctor blading of the silver paste. For example, the silver paste with a predetermined height may be filled at the bottom of the trench to reserve a portion of space in the trench, and in a subsequent step, the second electrode layer may also be disposed in the trench by using the reserved space. For another example, the silver paste may also be fully filled in the trench or the silver paste may be allowed to overflow from the trench.

In some other embodiments, the step S3 may specifically include:
disposing a photoresist on the transparent conductive film layer, exposing and developing the photoresist to form a transparent insulating layer with a trench in a grid shape, the transparent conductive film layer being exposed in the trench of the transparent insulating layer; and
filling the trench with silver paste and sintering the silver paste to form a silver seed layer serving as the first electrode layer, or, performing electroplating or electroless plating in the trench to form a silver seed layer serving as the first electrode layer.

The trench is formed by providing the transparent insulating layer, and then the first electrode layer and the second electrode layer are formed, so that a width of the resulting composite metal grid structure may not exceed 17 μm, which may break through a size limit of an existing process, and offer better electrical conductivity and a higher transmittance. Therefore, quality of the solar cell can be improved, and an increasingly higher size requirement in the market are further met.

In some embodiments, the preparation method of the solar cell further includes the following step: removing the transparent insulating layer.

The above curing resin or photoresist may be left on the transparent conductive film layer, or may be removed by cleaning or etching.

In some embodiments, the preparation method of the solar cell further includes the following step: preparing an anti-oxidation protection layer.

The anti-oxidation protection layer at least wraps the first electrode layer and the second electrode layer, and in this case, the composite metal grid structure includes the first electrode layer, the second electrode layer, and the anti-oxidation protection layer wrapping the first electrode layer and the second electrode layer. The composite metal grid structure disposed in this way exhibits excellent electrical performance and a stable structural property.

In other embodiments, the anti-oxidation protection layer may cover, with an entire surface, a side, provided with the first electrode layer and the second electrode layer, of the transparent conductive film layer. In other embodiments, in a case that the transparent insulating layer is not removed, or the transparent insulating layer is re-provided after the transparent insulating layer is removed, the anti-oxidation protection layer is disposed, as an entire surface, above a surface of the second electrode layer, so as to cover both the second electrode layer and the transparent insulating layer.

In some embodiments, the preparation method of the solar cell further includes the following step: providing a transparent insulating layer.

After the transparent insulating layer is removed in the above step, the transparent insulating layer may also be formed separately to meet requirements of refractive index, reflection, oxidation resistance and the like.

In some embodiments, the step S4 may specifically include: forming a copper electrode layer serving as the second electrode layer on the first electrode layer by electroplating, electroless plating, or filling followed by sintering.

For example, a copper material may be continuously filled in the trench and the copper material is sintered to form the copper electrode layer. Alternatively, the copper electrode layer may be formed by electroplating or electroless plating. The copper electrode layer obtained in this way has a width not exceeding 17 μm, is structurally stable and reliable, and has good electrical performance and a high transmittance.

In some embodiments, the step S4 may further include: depositing metal tin on the second electrode layer. A thickness of a tin layer ranges from 5 nm to 50 nm, the tin layer may play a role in protecting the second electrode layer, so that electrical performance is improved.

In the following, reference is made to the drawings, and a solar cell provided with a composite metal grid structure and a preparation method of the solar cell in the present disclosure are described by examples.

Referring to FIG. 1, the present disclosure discloses a solar cell 100 provided with a composite metal grid structure, which includes a substrate 1, a transparent conductive film layer 2 and the composite metal grid structure 3. The substrate 1 includes a first side surface 11 and a second side surface 12 opposite to each other, the transparent conductive film layer 2 is arranged, as an entire surface, on the first side surface 11, and the composite metal grid structure 3 is in a line shape or a grid shape and is arranged on the transparent conductive film layer 2. The composite metal grid structure 3 includes a first electrode layer 31 in electrical contact with the transparent conductive film layer 2 and a second electrode layer 32 arranged corresponding to the first electrode layer 31, and the first electrode layer 31 is located between the transparent conductive film layer 2 and the second electrode layer 32.

The composite metal grid structure is formed by providing the second electrode layer 32 on the first electrode layer 31, so that structural stability is relatively high, consumption of silver may be reduced to lower costs, electrical performance is good, and conversion efficiency can be improved.

Optionally, a thickness of the substrate 1 ranges from 50 μm to 300 μm; the transparent conductive film layer 2 is an ITO layer with a thickness ranging from 50 nm to 200 nm; the first electrode layer 31 is a silver seed layer with a thickness ranging from 100 nm to 800 nm or 1 μm to 3 μm; and the second electrode layer 32 is a copper electrode layer with a thickness ranging from 10 μm to 60 μm and a width ranging from 3 μm to 80 μm. In this way, consumption of silver can be greatly reduced to lower costs.

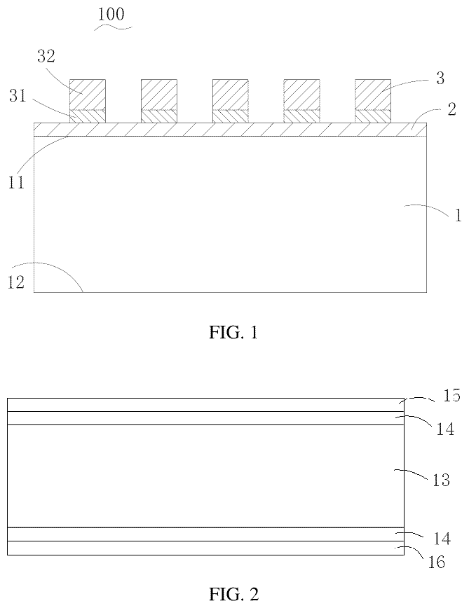

Optionally, referring to FIG. 2, the substrate 1 includes a silicon wafer 13, intrinsic amorphous silicon 14 and N-type doped amorphous silicon 15 located on a side of the silicon wafer 13, and intrinsic amorphous silicon 14 and P-type doped amorphous silicon 16 located on another side of the silicon wafer 13. Therefore, a PN junction can be formed, thereby obtaining a heterojunction solar cell.

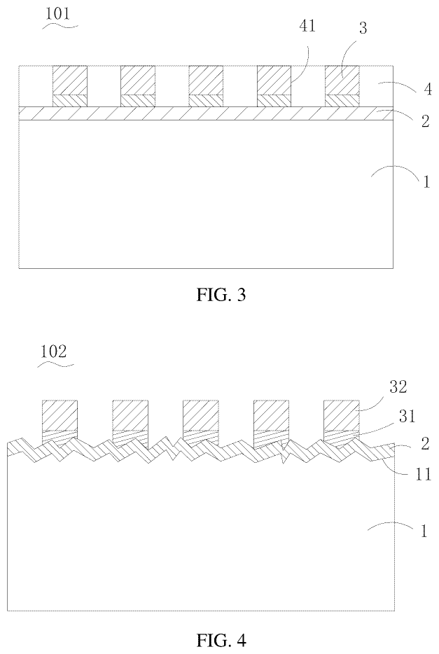

Referring to FIG. 3, which illustrates a solar cell 101 provided with a composite metal grid structure, and compared with the solar cell 100 shown in FIG. 1, the solar cell 101 of this embodiment further includes a transparent insulating layer 4. The transparent insulating layer 4 is disposed on a side, away from the substrate 1, of the transparent conductive film layer 2, the transparent insulating layer 4 is provided with a trench 41, and a composite metal grid structure 3 is disposed in the trench 41 and is in electrical contact with the transparent conductive film layer 2. In this embodiment, a height of the transparent insulating layer 4 is the same as a height of the composite metal grid structure 3.

In other embodiments, the transparent insulating layer 4 may be a composite layer including two or more layers, and a height of the composite layer may be higher than or lower than the height of the composite metal grid structure 3, for example, the height of the composite layer is equal to a height of the first electrode layer 31. In addition, the transparent insulating layer 4 may also be provided with an uneven surface to enhance illumination and improve efficiency.

Referring to FIG. 4, which illustrates a solar cell 102 provided with a composite metal grid structure, and compared with the solar cell 100 shown in FIG. 1, a first side surface 11 (i.e., a surface at a side close to the composite metal grid structure) of a substrate 1 of the solar cell 102 of this embodiment is a textured surface, which is uneven and has a height difference of no greater than 2 μm, thereby increasing surface energy. A transparent conductive film layer 2 is conformally arranged with the first side surface 11; a side, in contact with the transparent conductive film layer 2, of the first electrode layer 31 is also conformally arranged with the first side surface 11, and another side of the first electrode layer 31 is flat; and an upper side surface and a lower side surface of the second electrode layer 32 are both flat.

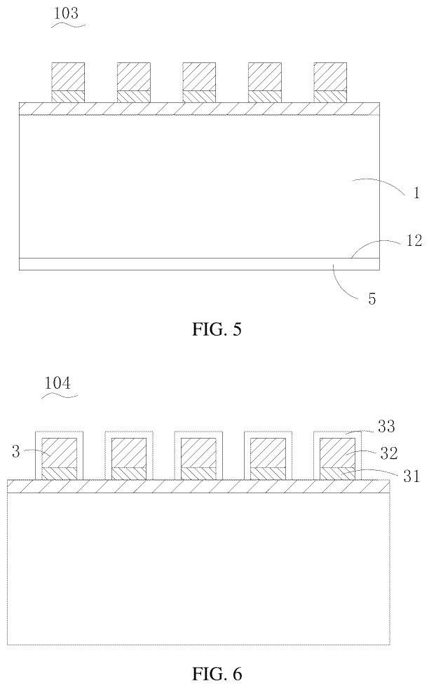

Referring to FIG. 5, which illustrates a solar cell 103 provided with a composite metal grid structure, and compared with the solar cell 100 provided with the composite metal grid structure shown in FIG. 1, the solar cell 103 of this embodiment further includes an anti-reflection layer 5 disposed on a second side surface 12 (i.e., a surface at a side away from the composite metal grid structure) of a substrate 1, thereby reducing reflection and improving conversion efficiency.

Referring to FIG. 6, which illustrates a solar cell 104 provided with a composite metal grid structure, and compared with the solar cell 100 shown in FIG. 1, a composite metal grid structure 3 of the solar cell 104 in this embodiment further includes an anti-oxidation protection layer 33. The anti-oxidation protection layer 33 wraps a first electrode layer 31 and a second electrode layer 32 to protect the first electrode layer 31 and the second electrode layer 32, thereby preventing the first electrode layer 31 and the second electrode layer 32 from being oxidized, thus improving an electrical effect and a service life of the composite metal grid structure 3.

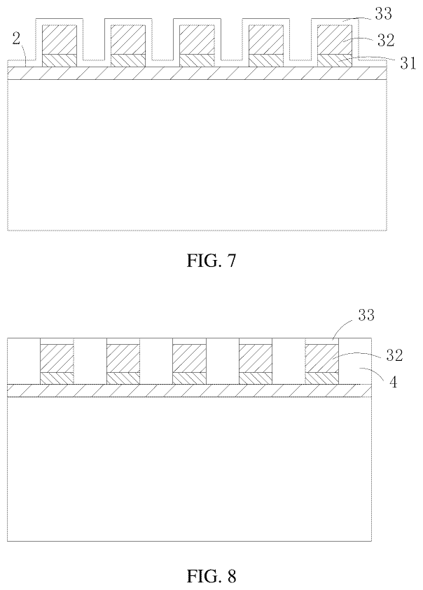

In other embodiments, referring to FIG. 7, an anti-oxidation protection layer 33 may also be applied as an entire surface, and therefore, the anti-oxidation protection layer 33 covers all of a first electrode layer 31, a second electrode layer 32, and an exposed transparent conductive film layer 2 to provide all-around protection.

In another embodiment, referring to FIG. 8, an anti-oxidation protection layer 33 may cover only a top surface of a second electrode layer 32, and another portion of the second electrode layer 32 are wrapped by a transparent insulating layer 4. Of course, in other embodiments, the anti-oxidation protection layer 33 may also cover, with an entire surface, the transparent insulating layer 4 and the second electrode layer 32.

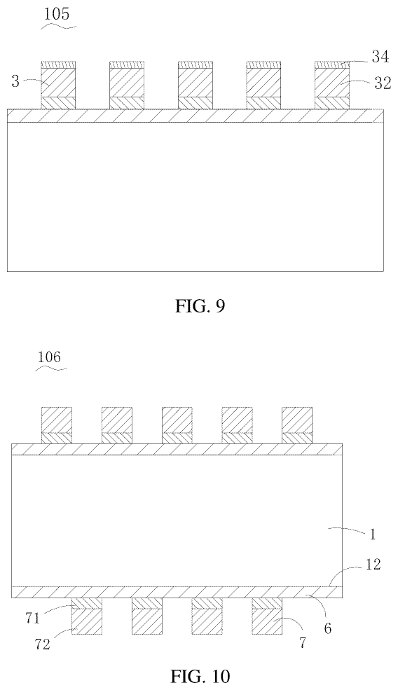

Referring to FIG. 9, which illustrates a solar cell 105 provided with a composite metal grid structure, and compared with the solar cell 100 shown in FIG. 1, a composite metal grid structure 3 of the solar cell 105 of this embodiment further includes a tin layer 34, a thickness of the tin layer 34 ranges from 5 nm to 50 nm, and the tin layer 34 may play a role in protecting a second electrode layer 32, thereby improving electrical performance.

Referring to FIG. 10, which illustrates a solar cell 106 provided with a composite metal grid structure, and compared with the solar cell 100 shown in FIG. 1, the solar cell 106 of this embodiment further includes a second transparent conductive film layer 6 and a second composite metal grid structure 7 that are located on a second side surface 12 of a substrate 1. The second transparent conductive film layer 6 is an ITO layer, the second composite metal grid structure 7 includes a third electrode layer 71 and a fourth electrode layer 72. In this way, a double-sided structure of the solar cell can be realized, so that an application scene is increased, conversion efficiency is improved, and consumption of silver is further reduced to lower costs.

Preferably, the third electrode layer 71 is a silver seed layer, and the fourth electrode layer 72 is a copper electrode layer. Similarly, in other embodiments, the first side surface and the second side surface of the solar cell may be selected as textured surfaces, and the solar cell may further include an anti-oxidation protection layer, a transparent insulating layer, a tin layer, and the like.

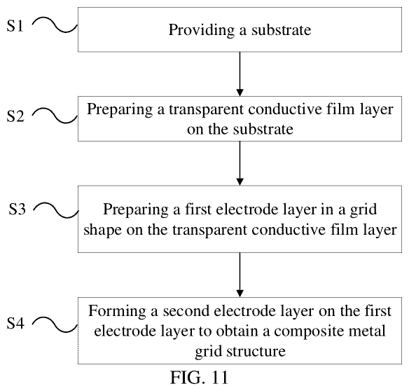

Referring to FIG. 11, a preparation method of a solar cell provided with a composite metal grid structure is disclosed, which includes following steps.

S1, providing a substrate.

The substrate may include a silicon wafer, intrinsic amorphous silicon, N-type doped amorphous silicon, P-type doped amorphous silicon, and the like.

S2, preparing a transparent conductive film layer on the substrate.

ITO with a thickness ranging from 50 nm to 200 nm is deposited on a first side surface of the substrate by a Physical Vapor Deposition (PVD) method, to form the transparent conductive film layer. In other embodiments, the ITO may be deposited on a second side surface, or the ITO may be deposited on both the first side surface and the second side surface. In the preparation method, the formation of the transparent conductive film layer on the first side surface is taken as an example, and a method for forming the transparent conductive film layer on the second side surface or both side surfaces may be referred to this preparation method.

S3, preparing a first electrode layer in a grid shape on the transparent conductive film layer.

As an example, the first electrode layer is a silver seed layer, UV resin is coated on the first side surface of the substrate, and the UV resin is imprinted and cures to form a trench in a grid shape; the residual UV resin at a bottom of the trench is removed to expose the transparent conductive film layer and to form a transparent insulating layer; and the trench is filled with silver paste, and the silver paste is sintered to form the silver seed layer with a thickness ranging from 1 μm to 3 μm. A shape of the trench corresponds to a shape of the composite metal grid structure. In other embodiments, a photoresist is coated on the first side surface of the substrate, and the photoresist exposes and develops to form a transparent insulating layer with a trench in a grid shape. In other embodiments, after the transparent conductive film layer is exposed, electroplating or electroless plating is performed to form a seed layer with a thickness ranging from 100 nm to 800 nm. A width of the trench is not greater than 17 μm, which breaks through a size limit, and meets more stringent size requirements.

S4, forming a second electrode layer on the first electrode layer to obtain a composite metal grid structure.

As an example, the second electrode layer is a copper electrode layer, and within the trench, a copper material is continuously filled on the first electrode layer through electroplating or electroless plating, to form the copper electrode layer. In other embodiments, a top surface or an entire surface of the copper electrode layer may be covered with an anti-oxidation protection layer.

In other embodiments, the preparation method of the solar cell may further include at least one of the following steps.

Removing the transparent insulating layer.

The curing resin or the photoresist above-mentioned may be left on the transparent conductive film layer (i.e., constituting the transparent insulating layer), or may be removed by processes such as cleaning or etching.

Preparing an anti-oxidation protective layer.

The anti-oxidation protection layer wraps the first electrode layer and the second electrode layer. In other embodiments, the anti-oxidation protection layer may also be applied as an entire surface.

Preparing a transparent insulating layer.

The transparent insulating layer is disposed in the grid gaps of the composite metal grid structure or is arranged, as an entire surface, on the composite metal grid structure.

The solar cell provided with the composite metal grid structure disclosed in the present disclosure has effects of saving costs, good electrical performance, and improving conversion efficiency. The preparation method has a simple process, using the preparation method saves costs, and a structure prepared by the preparation method is stable.

In order to make the above purposes, features and advantages of the present disclosure more comprehensible, specific embodiments of the present disclosure are described in detail above with reference to the accompanying drawings. In the foregoing description, numerous specific details are set forth in order to provide a thorough understanding of the present disclosure. However, the present disclosure can be implemented in many other manners different from those described above, and those skilled in the art may make similar improvements without departing from the connotation of the present disclosure, and therefore, the present disclosure is not limited by the specific embodiments disclosed above. In addition, the technical features of the above embodiments may be combined arbitrarily, and all possible combinations of the technical features in the above embodiments are not described for the sake of simplicity of description. However, as long as the combinations of these technical features do not conflict, they should be considered within the scope of this specification.

The above-mentioned embodiments only represent several embodiments of the present disclosure, and the description thereof is relatively specific and detailed, but cannot be understood as a limitation to the patent scope of the present disclosure. It should be noted that, as for a person of ordinary skill in the art, several modifications and improvements may also be made without departing from the concept of the present disclosure, which all fall within the protection scope of the present disclosure. Therefore, the protection scope of the present disclosure shall be subject to the appended claims.

1. A solar cell, comprising:
a substrate;
a transparent conductive film layer disposed on a side or both sides of the substrate; and
a composite metal grid structure disposed on a side, away from the substrate, of the transparent conductive film layer, the transparent conductive film layer being electrically connected to the composite metal grid structure,
wherein the composite metal grid structure comprises a first electrode layer and a second electrode layer that are stacked, and the first electrode layer is located between the transparent conductive film layer and the second electrode layer.

2. The solar cell according to claim 1, wherein the composite metal grid structure further comprises an anti-oxidation protection layer wrapping the first electrode layer and the second electrode layer.

3. The solar cell according to claim 1, wherein the first electrode layer is a silver seed layer, and the second electrode layer is a copper electrode layer.

4. The solar cell according to claim 1, wherein a width of the composite metal grid structure is less than or equal to 17 μm.

5. The solar cell according to claim 4, wherein an aspect ratio of the composite metal grid structure is greater than 0.5.

6. The solar cell according to claim 1, wherein the solar cell is a crystalline silicon solar cell or an amorphous silicon solar cell.

7. The solar cell according to claim 1, wherein the substrate comprises a first side surface and a second side surface opposite to each other, and the transparent conductive film layer is an Indium Tin Oxide (ITO) layer that is arranged, as an entire surface, on at least one of the first side surface or the second side surface.

8. The solar cell according to claim 1, wherein the substrate comprises a first side surface and a second side surface opposite to each other, at least one of the first side surface or the second side surface is a textured surface, a height difference on the textured surface is not greater than 2 μm, and the transparent conductive film layer is conformally arranged with the textured surface.

9. The solar cell according to claim 1, wherein the composite metal grid structure is arranged in a linear shape and/or a grid shape, and a transmittance of the composite metal grid structure is greater than 80%.

10. The solar cell according to claim 9, wherein the composite metal grid structure is in a polygonal grid shape, a circular grid shape, or a random grid shape.

11. The solar cell according to claim 1, wherein the first electrode layer is a coating layer having a thickness not greater than 800 nm, or the first electrode layer is a sintered layer having a thickness not greater than 3 μm; and
the second electrode layer is a sintered layer or a coating layer, and the second electrode layer has a thickness ranging from 5 μm to 60 μm and a width ranging from 3 μm to 80 μm.

12. The solar cell according to claim 1, further comprising: a transparent insulating layer,
wherein the transparent insulating layer is disposed on a side, away from the substrate, of the transparent conductive film layer, the transparent insulating layer is provided with a trench, and the composite metal grid structure is disposed in the trench and is in electrical contact with the transparent conductive film layer.

13. The solar cell according to claim 1, wherein the substrate comprises a first side surface and a second side surface opposite to each other, the first side surface is provided with the transparent conductive film layer and the composite metal grid structure, and the second side surface is provided with an anti-reflection layer.

14. A preparation method of a solar cell, comprising:
providing a substrate;
preparing a transparent conductive film layer on the substrate;
preparing a first electrode layer in a grid shape on the transparent conductive film layer; and
forming a second electrode layer on the first electrode layer to obtain a composite metal grid structure comprising the first electrode layer and the second electrode layer.

15. The preparation method according to claim 14, wherein the preparing a first electrode layer in a grid shape on the transparent conductive film layer comprises:
disposing curing resin on the transparent conductive film layer, imprinting and curing the curing resin to form a trench in a grid shape, and removing the curing resin at a bottom of the trench to form a transparent insulating layer, the transparent conductive film layer being exposed in the trench; and
filling the trench with silver paste and sintering the silver paste to form a silver seed layer serving as the first electrode layer, or, performing electroplating or electroless plating in the trench to form a silver seed layer serving as the first electrode layer.

16. The preparation method according to claim 15, further comprising:
removing the transparent insulating layer.

17. The preparation method according to claim 14, wherein the preparing a first electrode layer in a grid shape on the transparent conductive film layer comprises:
disposing a photoresist on the transparent conductive film layer, exposing and developing the photoresist to form a transparent insulating layer with a trench in a grid shape, the transparent conductive film layer being exposed in the trench; and
filling the trench with silver paste and sintering the silver paste to form a silver seed layer serving as the first electrode layer, or, performing electroplating or electroless plating in the trench to form a silver seed layer serving as the first electrode layer.

18. The preparation method according to claim 17, further comprising:
removing the transparent insulating layer.

19. The preparation method according to claim 14, further comprising:
preparing an anti-oxidation protection layer, wherein the anti-oxidation protection layer at least wraps the first electrode layer and the second electrode layer.

20. The preparation method according to claim 14, wherein the forming a second electrode layer on the first electrode layer to obtain a composite metal grid structure comprising the first electrode layer and the second electrode layer comprises:
forming a copper electrode layer serving as the second electrode layer on the first electrode layer by electroplating, electroless plating, or filling followed by sintering.
